(19) United States
(12) Patent Application Publication
(10) Pub. No.: US 2022/0109081 A1
(43) Pub. Date: Apr. 7, 2022

(54) TRANSFER SUBSTRATE

(71) Applicant: Japan Display Inc., Tokyo (JP)

(72) Inventor: Keisuke ASADA, Tokyo (JP)

(73) Assignee: Japan Display Inc., Tokyo (JP)

(21) Appl. No.: 17/552,458

(22) Filed: Dec. 16, 2021

Related U.S. Application Data
(63) Continuation of application No. PCT/JP2020/021217, filed on May 28, 2020.

(30) Foreign Application Priority Data
Jun. 26, 2019 (JP) 2019-118763

(51) Int. Cl. H01L 33/00; H01L 21/683

(52) U.S. Cl. CPC H01L 33/005; H01L 25/0753; H01L 2221/68309; H01L 21/6835

(57) ABSTRACT

A transfer substrate for an element includes a plurality of projection portions projecting from a first surface of an elastic body, and a first groove portion and a second groove portion. Each of the first groove portion and the second groove portion is depressed internally from the first surface of the elastic body and extends in a first direction. A depth of the second groove portion is greater than a depth of the first groove portion. Further, the first groove portion and the second groove portion are provided between the plurality of projection portions.

### CROSS-REFERENCE TO RELATED APPLICATIONS

This application is based on the PCT Application No. PCT/JP2020/021217, filed on May 28, 2020, and claims the benefit of priority from the prior Japanese Patent Application No. 2019-118763, filed on Jun. 26, 2019, and the entire contents of which are incorporated herein by reference.

### BACKGROUND OF THE INVENTION

### Field

One embodiment of the present invention relates to a transfer substrate for an element, which is used when the element is picked up from an element substrate on which the element is formed and the element is transferred to a circuit substrate on which a circuit for driving the element is formed.

### Description of the Related Art

In a small or medium-sized display device such as a smart phone, a display using liquid crystals or OLEDs (Organic Light Emitting Diodes) has been commercialized. In particular, an OLED display device using the OLEDs which are self-light emitting elements has the advantages of high-contrast and no need for a backlight, as compared with a liquid crystal display device. However, since the OLEDs are composed of organic compounds, it is difficult to secure high reliability of the OLED display device due to deterioration of the organic compounds.

On the other hand, a so-called micro LED display in which minute micro LEDs are placed in pixels arranged in a matrix has been developed as a next-generation display. The micro LEDs are self-emitting elements similar to the OLEDs, but unlike OLEDs, the micro LEDs are composed of inorganic compounds containing gallium (Ga) or indium (In). Therefore, it is easier to ensure a highly reliable micro LED display as compared with the OLED display. In addition, micro LEDs have high light emission efficiency and high brightness. Therefore, the micro LED display is expected to be the next generation display with high reliability, high brightness, and high contrast.

The micro LEDs are formed on a substrate such as sapphire similar to typical LEDs, and are separated into individual micro LEDs by dicing the substrate. In the micro LED display, it is necessary to place the diced micro LEDs in the pixels of a circuit substrate (also referred to as a backplane or a TFT substrate). As one of the methods for placing the micro LEDs on the circuit substrate, a transfer substrate is used to pick up a plurality of micro LEDs from an element substrate, the transfer substrate is attached to the circuit substrate, and the plurality of micro LEDs are transferred to the circuit substrate (See, for example, U.S. Patent Application Publication No. 2016/0240516 or U.S. Patent Application Publication No. 2017/0047306).

### SUMMARY OF THE INVENTION

A transfer substrate for an element according to an embodiment includes a plurality of projection portions projecting from a first surface of an elastic body, and a first groove portion and a second groove portion. Each of the first groove portion and the second groove portion is depressed internally from the first surface of the elastic body and extends in a first direction. A depth of the second groove portion is greater than a depth of the first groove portion. Further, the first groove portion and the second groove portion are provided between the plurality of projection portions.

### BRIEF DESCRIPTION OF THE DRAWINGS

FIG. 1 is a schematic perspective view of a transfer substrate according to an embodiment of the present invention;

FIG. 2A is a schematic cross-sectional view of a transfer substrate according to an embodiment of the present invention;

FIG. 2B is a schematic cross-sectional view of a transfer substrate according to an embodiment of the present invention;

FIG. 2C is a schematic partially enlarged view of a transfer substrate according to an embodiment of the present invention;

FIG. 3A is a schematic cross-sectional view of a transfer substrate according to an embodiment of the present invention;

FIG. 3B is a schematic cross-sectional view of a transfer substrate according to an embodiment of the present invention;

FIG. 3C is a schematic partially enlarged view of a transfer substrate according to an embodiment of the present invention;

FIG. 4A is a schematic cross-sectional view of a transfer substrate according to an embodiment of the present invention;

FIG. 4B is a schematic cross-sectional view of a transfer substrate according to an embodiment of the present invention;

FIG. 4C is a schematic partially enlarged view of a transfer substrate according to an embodiment of the present invention;

FIG. 5A is a schematic cross-sectional view of a transfer substrate according to an embodiment of the present invention;

FIG. 5B is a schematic cross-sectional view of a transfer substrate according to an embodiment of the present invention;

FIG. 5C is a schematic partially enlarged view of a transfer substrate according to an embodiment of the present invention;

FIG. 6 is a schematic perspective view of a transfer substrate according to an embodiment of the present invention;

FIG. 7A is a schematic cross-sectional view of a transfer substrate according to an embodiment of the present invention;

FIG. 7B is a schematic cross-sectional view of a transfer substrate according to an embodiment of the present invention;

FIG. 7C is a schematic partially enlarged view of a transfer substrate according to an embodiment of the present invention;

FIG. 8 is a schematic perspective view of a transfer substrate according to an embodiment of the present invention;

FIG. 9A is a schematic cross-sectional view of a transfer substrate according to an embodiment of the present invention;

FIG. 9B is a schematic cross-sectional view of a transfer substrate according to an embodiment of the present invention;

FIG. 9C is a schematic partially enlarged view of a transfer substrate according to an embodiment of the present invention;

FIG. 10 is a schematic perspective view of an element substrate used in a method for transferring an element according to an embodiment of the present invention;

FIG. 11 is a block diagram showing a layout configuration of a circuit substrate used in a method for transferring an element according to an embodiment of the present invention;

FIG. 12 is a schematic cross-sectional view of a TFT of a circuit substrate used in a method for transferring an element according to an embodiment of the present invention;

FIG. 13 is a flowchart of a method for transferring an element according to an embodiment of the present invention;

FIG. 14A is a schematic cross-sectional view showing a method for transferring an element according to an embodiment of the present invention;

FIG. 14B a schematic cross-sectional view showing a method for transferring an element according to an embodiment of the present invention;

FIG. 14C a schematic cross-sectional view showing a method for transferring an element according to an embodiment of the present invention;

FIG. 14D a schematic cross-sectional view showing a method for transferring an element according to an embodiment of the present invention;

FIG. 14E a schematic cross-sectional view showing a method for transferring an element according to an embodiment of the present invention;

FIG. 14F a schematic cross-sectional view showing a method for transferring an element according to an embodiment of the present invention;

FIG. 14G a schematic cross-sectional view showing a method for transferring an element according to an embodiment of the present invention;

FIG. 14H a schematic cross-sectional view showing a method for transferring an element according to an embodiment of the present invention; and

FIG. 15 a schematic cross-sectional view showing a method for transferring an element according to an embodiment of the present invention.

### DESCRIPTION OF EMBODIMENTS

In general, the size of the transfer substrate is smaller than the size of the circuit substrate, and the number of micro LEDs that can be picked up is limited. Therefore, it is necessary to repeat the transfer process. However, when further micro LEDs are transferred to the circuit substrate to which the micro LEDs are already bonded, the micro LED already bonded to the circuit substrate is in contact with the transfer substrate. As a result, there is a problem that the bonded micro LED is peeled off from the circuit substrate and re-picked up on the transfer substrate.

In view of the above problems, it is one object of the present invention to provide a transfer substrate that suppresses re-pickup of an element bonded to the circuit substrate.

Hereinafter, embodiments of the present invention are described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In each embodiment of the present invention, although the term “over” or “below” is used for convenience of explanation, the vertical relationship in the explanation may be reversed. For example, the expression “element over a substrate” merely explains the vertical relationship between the substrate and the element, and another member may be placed between the substrate and the element.

In the specification, the expressions “a includes A, B or C”, “a includes any of A, B and C”, and “a includes one selected from the group consisting of A, B and C” do not exclude the case where a includes a plurality of combinations of A to C unless otherwise specified. Further, these expressions do not exclude the case where a includes other elements.

In the specification, an element is, for example, a microelectromechanical system (MEMS), a laser diode (LD), a mini LED, a micro LED, or the like, but is not limited thereto.

In the specification, the mini LED is, for example, an LED having a size of 100 μm or more, and the micro LED is, for example, an LED having a size of several μm or more and less than 100 μm. However, in the specification, any size LED can be used according to a size of one pixel of a display device.

### First Embodiment

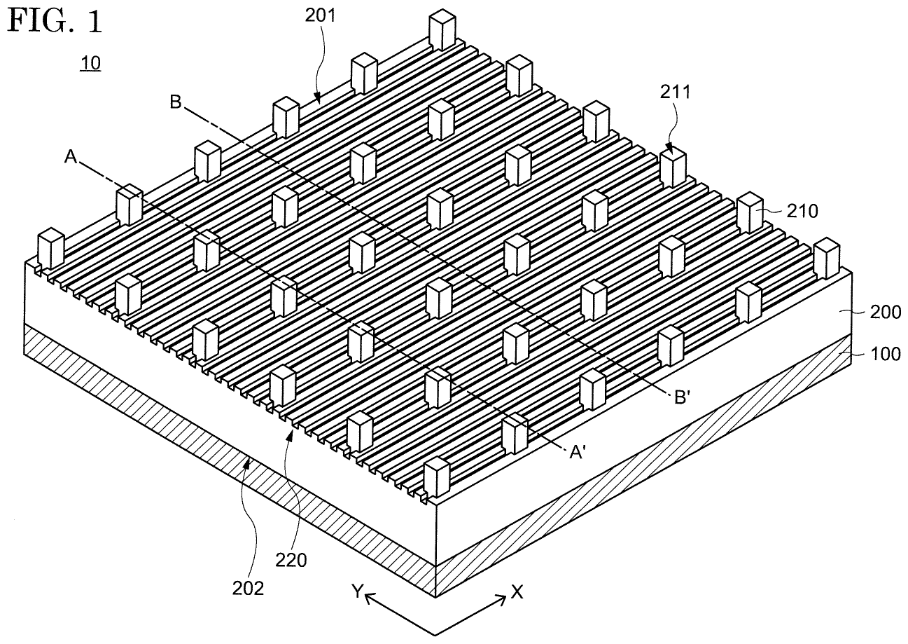

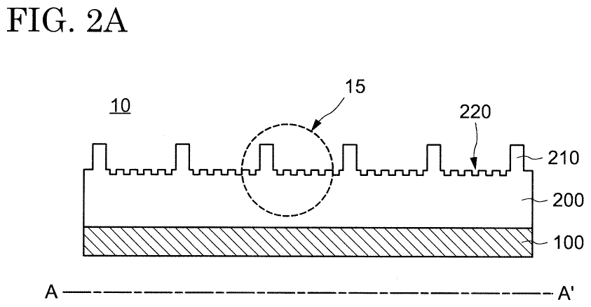

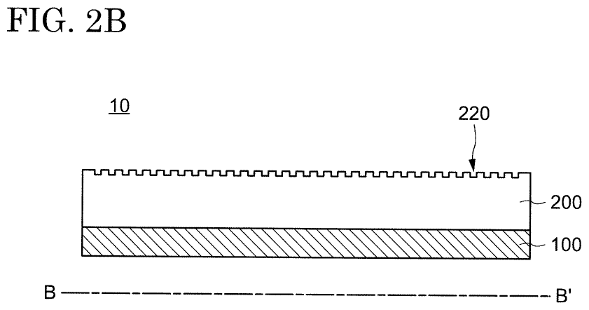

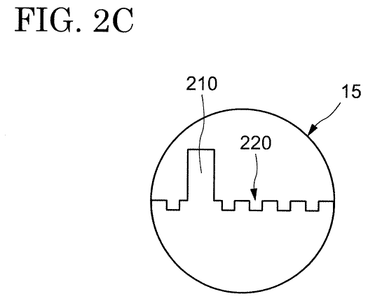

A transfer substrate 10 for an element according to an embodiment of the present invention is described with reference to FIGS. 1 and 2A to 2C.

### [Structure]

FIG. 1 is a schematic perspective view of the transfer substrate 10 according to the embodiment of the present invention. FIGS. 2A and 2B are schematic cross-sectional views of the transfer substrate 10 according to the embodiment of the present invention. Specifically, FIG. 2A is a schematic cross-sectional view cut along a line A-A′ of FIG. 1, and FIG. 2B is a schematic cross-sectional view cut along a line B-B′ of FIG. 1. Further, FIG. 2C is a schematic partially enlarged view of the transfer substrate 10 according to the embodiment of the present invention. Specifically, FIG. 2C is a schematic partially enlarged view of the transfer substrate 10 surrounded by a circle 15 of FIG. 2A.

The transfer substrate 10 includes a support 100 and an elastic body 200 provided on the support 100. The elastic body 200 includes a first surface 201 and a second surface 202 located on the opposite side of the first surface 201. A plurality of projection portions 210 and a plurality of groove portions 220 are provided on the first surface 201 of the elastic body 200. The first surface 201 of the elastic body 200 refers to the upper surface of the groove portion 220. That is, the projection portion 210 is a portion projecting from the first surface 201 of the elastic body 200, and the groove portion 220 is a portion recessed internally from the first surface 201 of the elastic body 200. Further, the support 100 is provided on the second surface 202 of the elastic body 200.

The size of the transfer substrate 10 can be determined as appropriate in consideration of the size of a substrate on which the element is formed (hereinafter, referred to as “first substrate”; also referred to as “element substrate”) or the size of a substrate on which a circuit is formed (hereinafter, referred to as “first substrate”, also referred to as “circuit substrate”). The size of the transfer substrate 10 is, for example, 50 mm square, but is not limited to this. Further, the shape of the transfer substrate 10 is, for example, a rectangle, but the shape is not limited to this. The shape of the transfer substrate 10 may be polygonal, circular, or elliptical.

It is preferable that an edge surface of the support 100 and an edge surface of the elastic body 200 of the transfer substrate 10 are aligned, but the transfer substrate 10 is not limited to this. The support 100 may be provided larger than the elastic body 200, or may be provided smaller than the elastic body 200. It is preferable that the support 100 is provided so as to uniformly transmit a force to the elastic body 200 when the force is applied to the support 100.

The projection portion 210 is provided to project from the first surface 200 so as to have a certain width in a first direction (X direction in FIG. 1) and a second direction (Y direction in FIG. 1), and a certain height in a direction perpendicular to the first surface 201 of the elastic body 200 (the direction perpendicular to the X direction and the Y direction). The width of the projection portion 210 in the first direction and the second direction can be appropriately determined in consideration of a size of the element picked up from the first substrate. Further, the height (or the vertical distance) of the projection portion 210 can be appropriately determined in consideration of the height of the element picked up from the first substrate. The height of the projection portion 210 is, for example, greater than or equal to 1 μm and less than or equal to 100 μm, preferably greater than or equal to 5 μm and less than or equal to 50 μm, and particularly preferably greater than or equal to 10 μm and less than or equal to 20 μm from the first surface 201 of the elastic body 200. If the height of the projection portion 210 exceeds 100 μm, the projection portion 210 is likely to be deformed in a direction other than the vertical direction when a picked-up element is transferred to the second substrate, so that a position in which the element is bonded to the second substrate is likely to shift. Further, if the height of the projection portion 210 is smaller than 1 μm, when the element is picked up from the first substrate, the element comes into close contact not only with the projection portion 210 but also with the first surface 201 or the groove portion 220 of the elastic body 200. Therefore, the height range of the projection portion 210 is preferably in the range described above.

The projection portion 210 has an upper surface 211 (hereinafter referred to as “head surface 211”). The head surface 211 has a function of being in contact with and picking up the element. Therefore, the head surface 211 has an adhesive strength that allows the element to be peeled off from the first substrate. The head surface 211 is preferably as flat as possible, and a surface roughness of the head surface 211 is preferably less than or equal to 1 μm. When the head surface 211 is flat, a contact area between the head surface 211 and the element increases, so that adhesion between the head surface 211 and the element can be increased. In other words, the adhesive strength of the head surface 211 can be increased by reducing the surface roughness of the head surface 211.

The projection portion 210 has a certain width in the first direction and the second direction. A cross-sectional shape of the projection portion 210 is rectangular, but is not limited to this. For example, the cross-sectional shape of the projection portion 210 can be polygonal, circular, or elliptical. That is, the projection portion 210 can have various shapes such as a polygonal pillar, a cylinder, or an elliptical pillar. Further, the projection portion 210 may be provided with a taper toward the head surface 211.

The number and spacing of the projection portions 210 can be appropriately determined in consideration of the size of the element to be picked up and a spacing of an arrangement of the elements of the second substrate to be transferred. For example, the projection portions 210 can be arranged in a matrix.

Each groove portion 220 is provided so as to extend linearly in the first direction. Further, a plurality of groove portions 220 is arranged in the second direction. That is, the groove portion 220 is provided extending from one edge surface of the elastic body 200 to the other edge surface in the first direction, and is provided between the projection portions 210 in the second direction. The depth (or vertical distance) of the groove portion 220 is, for example, greater than or equal to 1 μm and less than or equal to 30 μm, preferably greater than or equal to 2 μm and less than or equal to 10 μm, and particularly preferably greater than or equal to 2 μm and less than 3 μm. If the depth of the groove portion 220 is too shallow, when the projection portion 210 releases the picked-up element, a bottom surface of the groove portion 220 comes into contact with the element that is bonded to the second substrate, and the groove portion 220 picks up the element of the second substrate. Further, if the groove portion 220 is too deep, the rigidity of the transfer substrate 10 cannot be sufficiently maintained. Therefore, the range of the depth of the groove portion 220 is preferably in the range described above. Also, the depth of the groove portion 220 may be smaller than the height of the projection portion 210.

A cross-sectional shape of the groove portion 220 is rectangular and includes side surfaces and a bottom surface. The width of the groove portion 220 can be appropriately determined according to the size of the element. The width of the groove portion 220 is, for example, greater than or equal to 1 μm and less than or equal to 30 μm, preferably greater than or equal to 2 μm and less than or equal to 10 μm, and particularly preferably greater than or equal to 2 μm and less than or equal to 3 μm. Further, the number and spacing of the groove portions 220 can be appropriately determined in consideration of the size of the element and the spacing of the arrangement of the elements of the second substrate. Furthermore, the groove portion 220 may be tapered toward the bottom surface.

### [Material]

The support 100 has a function of supporting the elastic body 200 and increasing the rigidity of the transfer substrate 10. Therefore, the support 100 is preferably made of a material harder than the elastic body 200. For example, quartz, glass, sapphire, silicon, stainless steel, or the like can be used as a material of the support 100. If the rigidity of the transfer substrate 10 is sufficient only with the elastic body 200, it is not necessary to provide the transfer substrate 10 with the support 100.

The elastic body 200 has a function of absorbing a repulsive force from the element when the element is picked up or released. That is, the elastic body 200 has a property of being deformed when a force is applied and returning to its original state when the force is removed. For example, a natural rubber (NR), a silicone rubber (SI), a polyurethane rubber (PUR), a fluororubber (FPM), nitrile rubber (NBR), a styrene-butadiene rubber (SBR), a butadiene rubber. (BR), an isoprene rubber (IR), an ethylene propylene diene rubber (EPDM), an acrylic rubber (ACM), an isobutyene isoprene rubber (IIR), or the like, or materials made of these rubbers alone or in combination can be used for the elastic body 200. In particular, when high heat resistance is required, the material of the elastic body 200 is preferably silicone rubber or fluororubber. In the present specification, the silicone rubber includes a polydimethylsiloxane (PDMS).

Further, the elastic body 200 may contain additives such as a vulcanizing material, a filler, a softener, a coloring agent, and an anti-deterioration agent. Sulfur, a sulfur compound, a peroxide, or the like can be used as the vulcanizing material. Barium sulfate, calcium carbonate, silicic acid, magnesium silicate, calcium silicate, or the like can be used as the filler. Paraffin-based process oil, naphthenic process oil, or the like can be used as the softener. Carbon black, titanium white, ultramarine blue, phthalocyanine, red iron oxide, lead chromate, or the like can be used as the coloring agent. Phenol, wax, or the like can be used as the anti-deterioration agent.

Further, the elastic body 200 may contain a vulcanization aid or a vulcanization accelerator. Zinc stearate, stearate, zinc white, zinc oxide, magnesium oxide, or the like can be used as the vulcanization aid. Thiazoles, thiraums, sulfenamides, dithiocarbamate, or the like may be used as the vulcanization accelerator.

Although the support 100 is provided on the second surface 202 of the elastic body 200, the elastic body 200 and the support 100 may be adhered to each other by using an adhesive. Acrylic resin, polyester resin, vinyl chloride/vinyl acetate copolymer resin, ethylene/acrylic acid ester copolymer resin, ethylene/methacrylate copolymer resin, polyamide resin, polyolefin resin, chlorinated polyolefin resin, epoxy resin, urethane resin, or the like can be used as the adhesive.

Since the groove portion 220 of the transfer substrate 10 for the element according to the present embodiment is provided on the first surface 201 of the elastic body 200, the first surface 201 has a smaller contact area with the element than the head surface 211. Therefore, when a further element is transferred to the second substrate to which the element is already bonded by using the transfer substrate 10, even if the element bonded to the second substrate comes in contact with the first surface 201 of the transfer substrate 10, the first surface 201 does not re-pick up the element because the contact area is small. Therefore, defects in the transfer process of the element are suppressed, and the yield is improved.

### [Modifications]

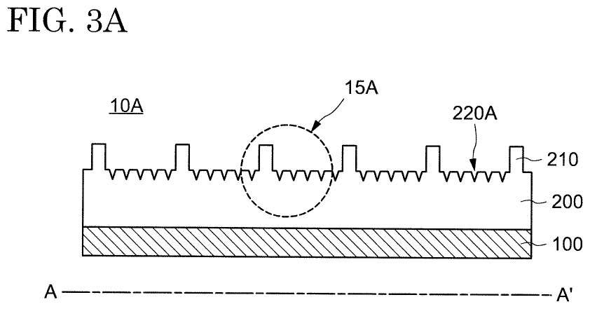

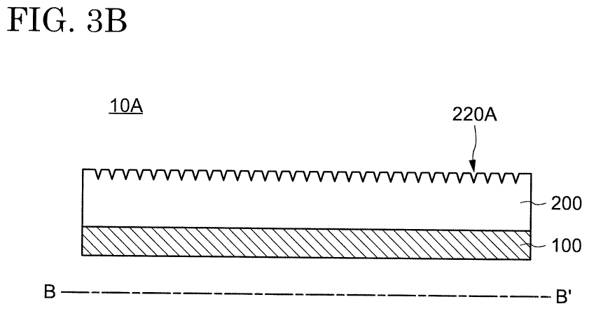

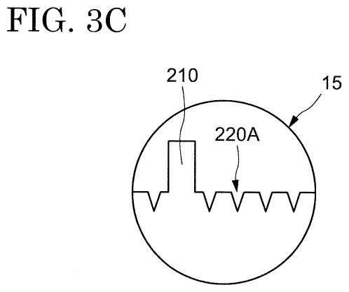

Modifications of the transfer substrate for the element according to the present embodiment are described with reference to FIGS. 3A to 5C. In the following explanation, a schematic perspective view of the transfer substrate according to the modification is omitted, and a schematic cross-sectional view and a schematic partially enlarged view is described. However, for convenience, the line A-A′ represents a cross-sectional surface including a projection portion, and the line B-B′ represents a cross-sectional surface not including the projection portion, as shown in FIG. 1.

FIGS. 3A and 3B are schematic cross-sectional views of a transfer substrate 10A according to the embodiment of the present invention. Specifically, FIG. 3A is a schematic cross-sectional view cut along the line A-A′, and FIG. 3B is a schematic cross-sectional view cut along the line B-B′. Further, FIG. 3C is a schematic partially enlarged view of the transfer substrate 10A according to the embodiment of the present invention. Specifically, FIG. 3C is a schematic partially enlarged view of the transfer substrate 10A surrounded by a circle 15A of FIG. 3A.

The cross-sectional shape of the groove of the transfer substrate 10A is different to the transfer substrate 10. The cross-sectional shape of a groove portion 220A of the transfer substrate 10A is triangular. The cross-sectional shape of the groove portion 220A is not limited to the isosceles triangle as shown in FIGS. 3A to 3C. The triangle may be a regular triangle, a right triangle, an acute triangle, or an obtuse triangle. Also, a corner of the triangle does not necessarily have to be sharp and may be rounded. Further, although not shown, a flat surface may not be provided between the groove portions 220A, and the groove portion 220A may be provided so as to connect two adjacent groove portions 220A to form a ridge line.

Since the groove portion 220A of the transfer substrate 10A for the element according to the modification is provided on the first surface 201 of the elastic body 200, the first surface 201 has a smaller contact area with the element than the head surface 211. Therefore, when a further element is transferred to the second substrate to which the element is already bonded by using the transfer substrate 10A, even if the element bonded to the second substrate comes in contact with the first surface 201 of the transfer substrate 10A, the first surface 201 does not re-pick up the element because the contact area is small. Further, the cross-sectional shape of the groove portion 220A is triangular, and the groove portion 220A does not have a bottom surface. Therefore, the groove portion 220A does not re-pick up the element. Therefore, defects in the transfer process of the element are suppressed, and the yield is improved.

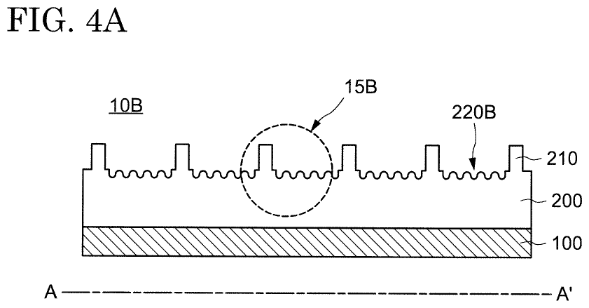

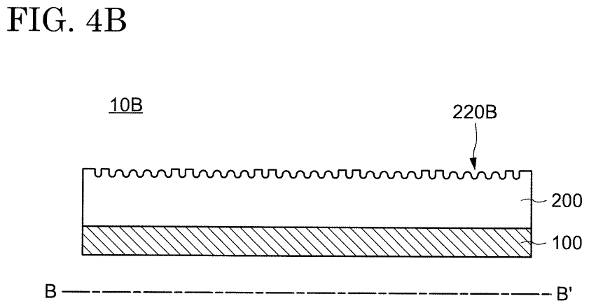

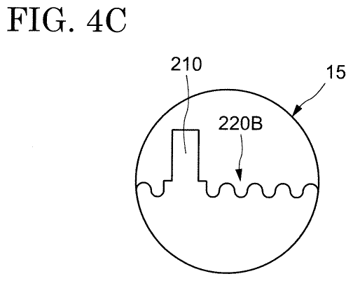

FIGS. 4A and 4B are schematic cross-sectional views of a transfer substrate 10B according to an embodiment of the present invention. Specifically, FIG. 4A is a schematic cross-sectional view cut along the line A-A′, and FIG. 4B is a schematic cross-sectional view cut along the line B-B′. Further, FIG. 4C is a schematic partially enlarged view of the transfer substrate 10B according to the embodiment of the present invention. Specifically, FIG. 4C is a schematic partially enlarged view of the transfer substrate 10B surrounded by a circle 15B of FIG. 4A.

The cross-sectional shape of the groove of the transfer substrate 10B is different to the transfer substrate 10. The cross-sectional shape of the groove portion 220B of the transfer substrate 10B is semicircular. Further, the cross-sectional shape of a convex portion between the groove portions 220B is also semicircular. The cross-sectional shape of the groove portion 220B is not limited to a semicircular shape, and may be a semi-elliptical shape. That is, the groove portion 220B may be formed with a curved surface. The convex portion between the groove portions 220B has the same configuration.

Since the groove portion 220B of the transfer substrate 10B for the element according to the modification is provided on the first surface 201 of the elastic body 200, the first surface 201 has a smaller contact area with the element than the head surface 211. Therefore, when a further element is transferred to the second substrate to which the element is already bonded by using the transfer substrate 10B, even if the element bonded to the second substrate comes in contact with the first surface 201 of the transfer substrate 10A, the first surface 201 does not re-pick up the element because the contact area is small. Further, the groove portion 220B has a curved surface, and the bottom surface of the groove portion 220B is not flat. Furthermore, the convex portion between the groove portions 220B also has a curved surface, and the first surface 201 is not a flat surface. Therefore, the groove portion 220B does not re-pick up the element. Therefore, defects in the transfer process of the element are suppressed, and the yield is improved.

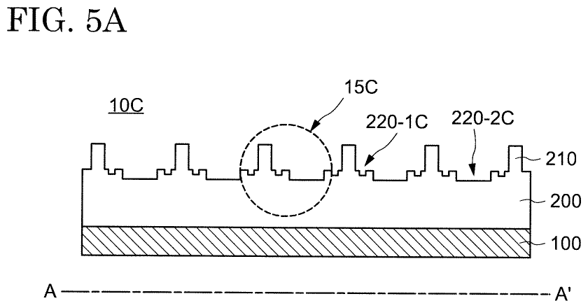

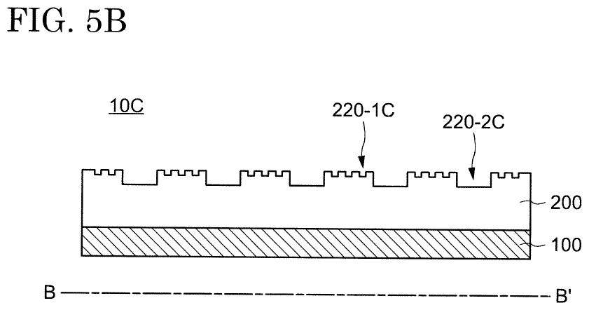

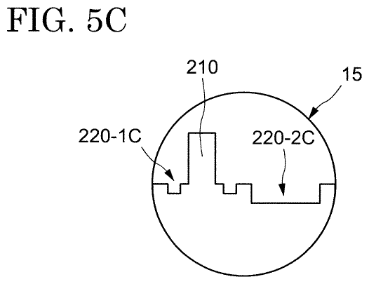

FIGS. 5A and 5B are schematic cross-sectional views of a transfer substrate 10C according to the embodiment of the present invention. Specifically, FIG. 5A is a schematic cross-sectional view cut along the line A-A′, and FIG. 5B is a schematic cross-sectional view cut along the line B-B′. Further, FIG. 5C is a schematic partially enlarged view of the transfer substrate 10C according to the embodiment of the present invention. Specifically, FIG. 5C is a schematic partially enlarged view of the transfer substrate 10C surrounded by a circle 15C of FIG. 5A.

The cross-sectional shape of the groove of the transfer substrate 10C is different to the transfer substrate 10. The transfer substrate 10C includes a first groove portion 220-1C and a second groove portion 220-2C. The depth of the second groove portion 220-2C is deeper than the depth of the first groove portion 220-1C. A plurality of first groove portions 220-1C and a plurality of second groove portions 220-2C may be provided between the projection portions 210. Further, the first groove portion 220-1C and the second groove portion 220-2C can be provided alternately.

Since the first groove portion 220C-1 and the second groove portion 220C-2 of the transfer substrate 10C for the element according to the modification are provided on the first surface 201 of the elastic body 200, the first surface 201 has a smaller contact area with the element than the head surface 211. Therefore, when a further element is transferred to the second substrate to which the element is already bonded by using the transfer substrate 10B, even if the element bonded to the second substrate comes in contact with the first surface 201 of the transfer substrate 10A, the first surface 201 does not re-pick up the element because the contact area is small. Therefore, defects in the transfer process of the element are suppressed, and the yield is improved. In addition, by providing the groove portions having two different depths, a compressive strain of the projection portion 210 can be distributed. That is, in the transfer substrate 10C, the shift in the position when the projection portion 210 is compressed is small. Therefore, the element can be picked up with high accuracy.

In addition, although not shown in the diagram, the groove portion 220 may be extended in a curved line instead of a straight line in the first direction. For example, the groove portion 220 can be extended in a wavy line in the first direction.

Further, instead of a depression extending in one direction such as the groove portion 220, a large number of concave portions may be provided to form the first surface 201 having irregularities. Furthermore, the first surface of the elastic body 200 may be satin-finished to form the first surface 201 having unevenness. In such an embodiment, a surface roughness of the first surface 201 is larger than an average roughness of the head surface 211, so that the first surface 201 has a smaller contact area with the element than the head surface 211. Therefore, even in such an embodiment, the re-pickup of the element by the first surface 201 can be suppressed.

As can be seen from the above explanation, it can also be said that the transfer substrate for the element according to the embodiment of the present invention includes a projection portion which is a means for picking up the element on the first substrate and a groove portion which is a means for not picking up the element on the second substrate.

The above configuration is merely one embodiment including modifications, and the present invention is not limited to the above configuration.

### Second Embodiment

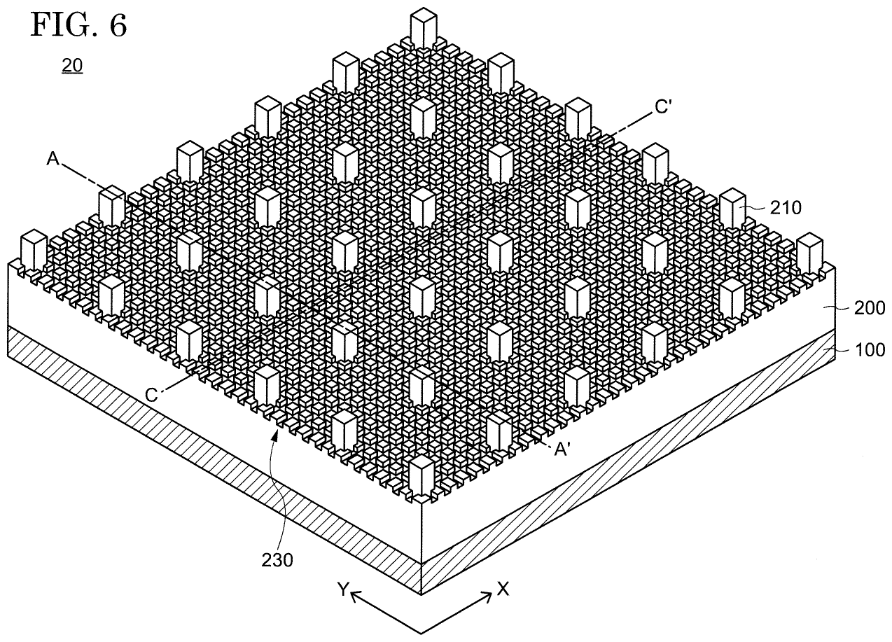

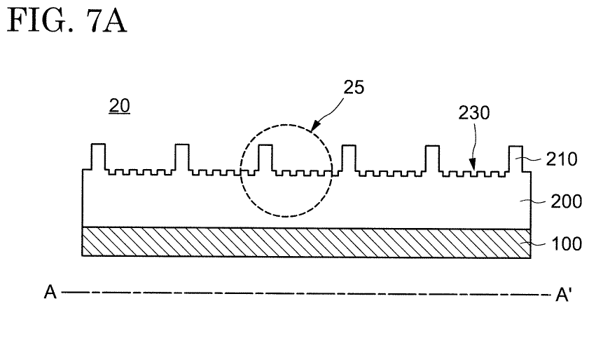

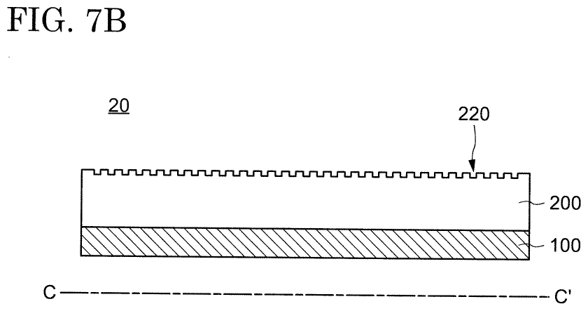

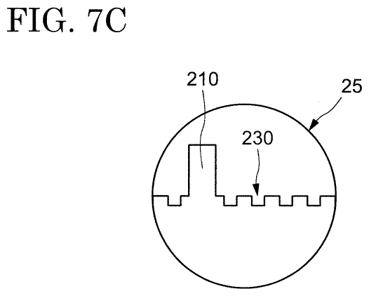

A transfer substrate 20 for an element according to an embodiment of the present invention, which is different from the First Embodiment, is described with reference to FIGS. 6 and 7A to 7C. In the following explanation, a description of the same configuration as in the First Embodiment is omitted, and the configuration different from the First Embodiment is mainly described.

FIG. 6 is a schematic perspective view of the transfer substrate 20 according to the embodiment of the present invention. FIGS. 7A and 7B are schematic cross-sectional views of the transfer substrate 20 according to the embodiment of the present invention. Specifically, FIG. 7A is a schematic cross-sectional view cut along a line A-A′ of FIG. 6, and FIG. 7B is a schematic cross-sectional view cut along a line C-C′ of FIG. 6. The line C-C′ is orthogonal to the line A-A′. Further, FIG. 7C is a schematic partially enlarged view of the transfer substrate 20 according to the embodiment of the present invention. Specifically, FIG. 7C is a schematic partially enlarged view of the transfer substrate 20 surrounded by a circle 25 of FIG. 7A.

The transfer substrate 10 includes a support 100 and an elastic body 200 provided on the support 100. The elastic body 200 includes a first surface 201 and a second surface 202 located on the opposite side of the first surface 201. On the first surface 201 of the elastic body 200, a groove portion 230 is provided between the plurality of projection portions 210 and the plurality of projection portions 210. That is, the transfer substrate 20 has a groove shape different from that of the transfer substrate 10 according to the First Embodiment.

The groove portion 230 of the transfer substrate 20 is provided in a grid pattern. That is, grooves (first grooves) linearly extending in the first direction and grooves (second grooves) linearly extending in the second direction are provided orthogonally to each other. In the transfer substrate 20 shown in FIGS. 6 and 7A to 7C, the first groove and second groove are the same in depth and width, and have the same cross-sectional shape, but is not limited thereto. The first groove and the second groove may differ in depth, width or have a different cross-sectional shape. Further, the first groove or the second groove may be provided with a taper toward a bottom surface. For example, the cross-sectional shape of the first groove may be rectangular, and the cross-sectional shape of the second groove may be circular. The depth, width, or cross-sectional shape of each of the first groove and the second groove can be appropriately determined in consideration of the size of the element and the spacing of the arrangement of the elements on the second substrate.

In the transfer substrate 20 shown in FIGS. 6 and 7A to 7C, the first grooves and the second grooves are arranged at equal intervals, and the first groove and the second groove are orthogonal (intersect at 90°). Therefore, the shape of the first surface 201 surrounded by the first grooves and the second grooves is square. On the other hand, the interval between the first grooves or the second grooves may be changed so that the shape of the first surface 201 surrounded by the first groove and the second groove can be made rectangular. Further, in the groove portion 230, the first groove and the second groove may intersect at an angle other than 90°, and the shape of the first surface 201 surrounded by the first groove and the second groove can be a parallelogram or a rhombus.

Since the groove portion 230 of the transfer substrate 20 for the element according to the present embodiment is provided on the first surface 201 of the elastic body 200, the first surface 201 has a smaller contact area with the element than the head surface 211. Therefore, when a further element is transferred to the second substrate to which the element is already bonded by using the transfer substrate 20, even if the element bonded to the second substrate comes in contact with the first surface 201 of the transfer substrate 20, the first surface 201 does not re-pick up the element because the contact area is small. Further, the groove portion 230 includes the first grooves and the second grooves in the direction different from that of the first grooves. Therefore, even when the first surface 201 is in contact with the element, a gap can be formed not only in the first groove but also in the second grooves to prevent a space between the surface 201 and the element from being maintained in a vacuum state. Therefore, defects in the transfer process of the element are suppressed, and the yield is improved.

### Third Embodiment

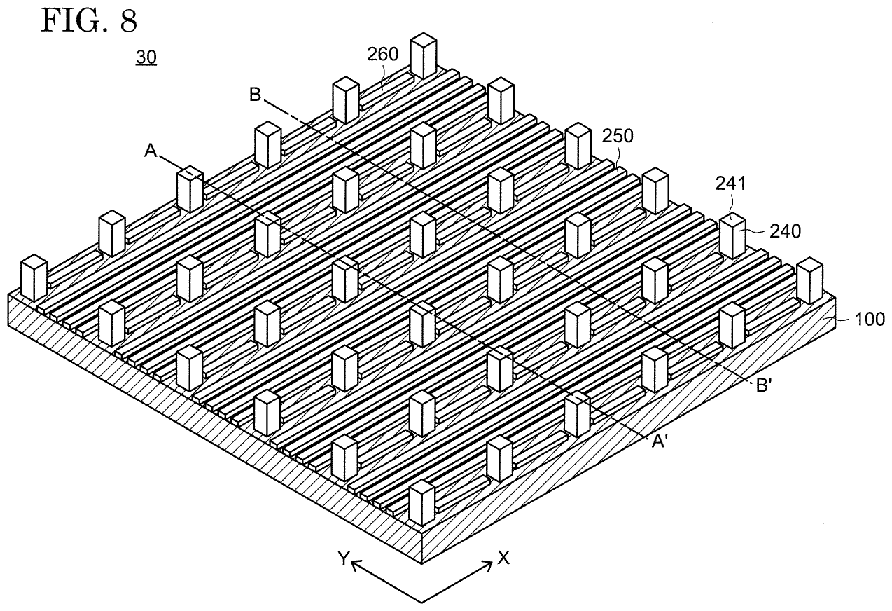

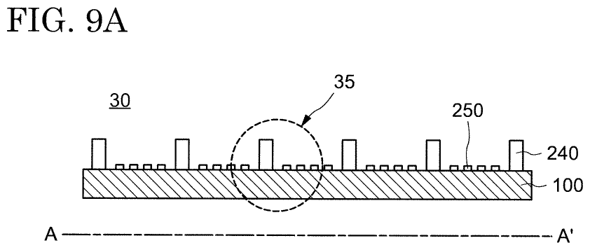

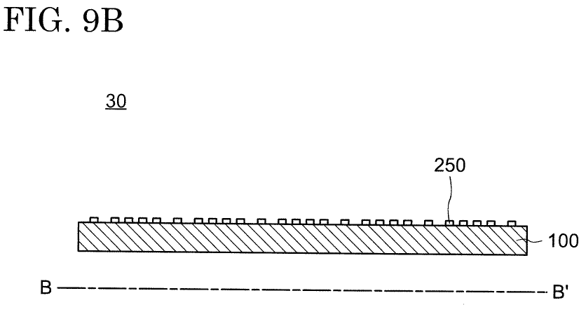

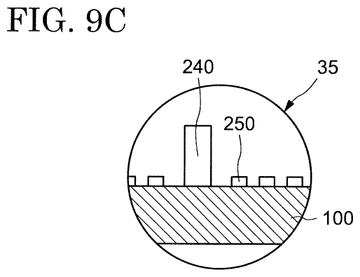

A transfer substrate 30 for an element according to an embodiment of the present invention, which is different from the First Embodiment and the Second Embodiment, is described with reference to FIGS. 8 and 9A to 9C. In the following explanation, a description of the same configuration as in the First Embodiment and the Second Embodiment is omitted, and the configuration different from the First Embodiment and the Second Embodiment is mainly described.

FIG. 8 is a schematic perspective view of the transfer substrate 30 according to the embodiment of the present invention. FIGS. 9A and 9B are schematic cross-sectional views of the transfer substrate 30 according to the embodiment of the present invention. Specifically, FIG. 9A is a schematic cross-sectional view cut along a line A-A′ of FIG. 8, and FIG. 9B is a schematic cross-sectional view cut along a line B-B′ of FIG. 8. Further, FIG. 9C is a schematic partially enlarged view of the transfer substrate 30 according to the embodiment of the present invention. Specifically, FIG. 9C is a schematic partially enlarged view of the transfer substrate 30 surrounded by a circle 35 of FIG. 9A.

The transfer substrate 30 includes the support 100, a first elastic body 240, a second elastic body 250, and a third elastic body 260. The first elastic body 240, the second elastic body 250, and the third elastic body 260 are provided on the support 100.

A plurality of first elastic bodies 240 is arranged in a matrix on the support 100. A plurality of second elastic bodies 250 is arranged between the first elastic bodies 240 in the second direction (Y direction in FIG. 8). The third elastic body 260 is arranged between the adjacent first elastic bodies 240 in the first direction (X direction in FIG. 8).

The first elastic body 240 has a certain length in the first direction and the second direction, and a certain length in a third direction perpendicular to the first direction and the second direction. In the first elastic body 240 shown in FIGS. 8 and 9A to 9C, the length in the third direction is larger than the length in the first direction and the length in the second direction, but not limited to this. The length of the first elastic body 240 in the first direction and the second direction may be smaller than the length in the third direction. Further, the first elastic body 240 shown in FIGS. 8 and 9A to 9C is a square prism (rectangular parallelepiped), but not limited to this. The shape of the first elastic body 240 may be, for example, a polygonal prism such as a triangular prism or a pentagonal prism, or a cylinder or an elliptical prism.

An upper surface of the first elastic body 240 in the third direction functions as a head surface 241 that is in contact with the element and picks up the element. The head surface 241 has an adhesive strength that allows the element to be peeled off from the first substrate.

The second elastic body 250 has a certain length in the second direction and the third direction, and has a structure extended in the first direction. The length of the second elastic body 250 in the third direction is smaller than the length of the first elastic body 240 in the third direction. The length of the second elastic body 250 in the first direction may be the same as or less than the width of the support 100.

The third elastic body 260 has a certain length in the second direction and the third direction, and has a structure extended in the first direction. The length of the third elastic body 260 in the third direction is smaller than the length of the first elastic body 240 in the third direction and is the same as the length of the second elastic body 250 in the third direction. The length of the third elastic body 260 in the first direction is smaller than the length of the second elastic body 250 in the first direction.

Since there is a gap between the second elastic body 250 and the third elastic body 260, the transfer substrate 30 includes a structure in which it is difficult to adsorb the element. In other words, it can be said that a portion of the transfer substrate 30 other than the head surface 241 has a small adhesive strength.

The first elastic body 240, the second elastic body 250, and the third elastic body 260 can be formed of the same material as the elastic body 200 according to the First Embodiment. The first elastic body 240, the second elastic body 250, and the third elastic body 260 may be formed of the same material or of different materials.

The first elastic body 240, the second elastic body 250, and the third elastic body 260 can also be formed by forming a film of an elastic material on the support 100 and processing it by laser or etching. Alternatively, the first elastic body 240, the second elastic body 250, and the third elastic body 260 may be processed beforehand, and they may be bonded to the support 100 via an adhesive.

The transfer substrate 30 for the element according to the present embodiment is provided with the first elastic body 240 on the support 100, and the element is picked up by the head surface 241 of the first elastic body 240. Further, the second elastic body 250 and the third elastic body 260 are provided between the first elastic body 240 to provide unevenness on the support 100 to reduce the contact area between the element and portions other than the head surface 241. Therefore, when a further element is transferred to the second substrate to which the element is already bonded by using the transfer substrate 30, even if the element bonded to the second substrate comes in contact with the second elastic body 250 and the third elastic body 260 of the transfer substrate 30, the transfer substrate 30 does not re-pick up the element. Therefore, defects in the transfer process of the element are suppressed, and the yield is improved.

### Fourth Embodiment

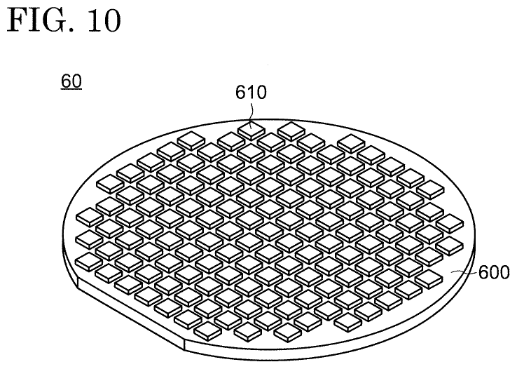

A method for transferring an element according to an embodiment of the present invention is described with reference to FIGS. 10 to 15. Specifically, this embodiment describes a method of transferring an element from an element substrate (first substrate) on which the element is formed to a circuit substrate (second substrate) on which a circuit for driving the element is formed, using the transfer substrate 10 for the element according to the First Embodiment.

### [1. Element Substrate (First Substrate)]

FIG. 10 is a schematic perspective view of an element substrate 60 used in the method for transferring the element according to the embodiment of the present invention.

As shown in FIG. 10, the element substrate 60 includes a support substrate 600 and a plurality of elements 610. Further, the plurality of elements 610 are arranged in a matrix on the support substrate 600, but not limited to this. The plurality of elements 610 may be arranged in a staggered manner on the support substrate 600.

A rigid substrate such as quartz, glass, or silicon, or a flexible substrate such as polyimide, acrylic, polyethylene naphthalate (PEN), or polyethylene terephthalate (PET) can be used as the support substrate 600. Further, the support substrate 600 is not limited to a substrate, and may be a film or a sheet.

The support substrate 600 may be a base material or a wafer used for manufacturing the element. In the case of an element using a silicon semiconductor, a silicon wafer can be used as the support substrate 600. Further, in the case of an element using a compound semiconductor, a sapphire substrate can be used as the support substrate 600.

Further, the support substrate 600 may be a dicing film or a dicing sheet. After forming the element on the base material or the wafer, the dicing film or the dicing sheet is attached to the base material or the wafer and dicing of the base material or the wafer is performed. In this case, the dicing film or the dicing sheet is the support substrate 600. Further, the element 610 includes the base material or the wafer on which the element is formed.

Furthermore, the elements 610 after dicing the base material or the wafer can be arranged on another substrate, film, or sheet, which can be used as the support substrate 600.

The element substrate 60 is a substrate that serves as a transfer source. The element substrate 60 is not limited to the above configuration. In the element substrate 60, the elements 610 to be transferred may be separately arranged on the support substrate 600 so that the transfer substrate 10 can pick up the elements 610.

### [2. Circuit Substrate (Second Substrate)]

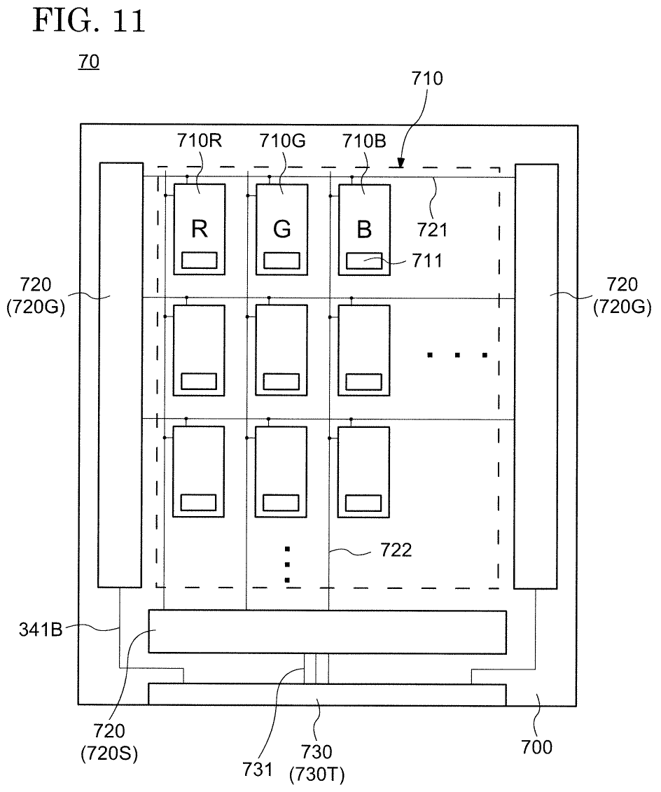

FIG. 11 is a block diagram showing a layout configuration of the circuit substrate 70 used in the method for transferring the element according to the embodiment of the present invention. Specifically, the circuit substrate 70 is for a display device, and FIG. 11 shows regions and a connection relationship provided on the substrate 700 included in the circuit substrate 70. The circuit substrate 70 used in this embodiment is not limited to the display device.

A translucent substrate such as a glass substrate, a quartz substrate, a sapphire substrate, a polyimide substrate, an acrylic substrate, a siloxane substrate, or a fluororesin substrate can be used as the substrate 700. Further, when translucency is not required, a semiconductor substrate such as a silicon substrate, a silicon carbide substrate, or a compound semiconductor substrate, or a conductive substrate such as a stainless steel substrate can be used as the substrate 700.

As shown in FIG. 11, a pixel region 710, a driver circuit region 720, and a terminal region 730 are provided on the substrate 700. The driver circuit region 720 and the terminal region 730 are provided around the pixel region 710.

The pixel region 710 includes a plurality of red light emitting pixels 710R, a plurality of green light emitting pixels 710G, and a plurality of blue light emitting pixels 710B which are arranged in a matrix. A pixel circuit 711 is provided in each pixel. Although not shown in the diagram, an electrode electrically connected to the element 610 is provided in each pixel. Further, although not shown in the diagram, a conductive adhesive is provided on the electrode in order to bond the element 610 and the electrode.

The driver circuit region 720 includes a gate driver circuit 720G and a source driver circuit 720S. The pixel circuit 711 and the gate driver circuit 720G are connected via a gate wiring 721. Further, the pixel circuit 711 and the source driver circuit 720S are connected via a source wiring 722. The red light emitting pixel 710R, the green light emitting pixel 710G, and the blue light emitting pixel 710B are provided at positions where the gate wiring 721 and the source wiring 722 intersect.

The terminal region 730 includes a terminal portion 730T for connecting to an external device. The terminal portion 730T and the gate driver circuit 720G are connected through a connection wiring 731. Further, the terminal portion 730T and the source driver circuit 720S are connected through a connection wiring 732. By connecting a flexible printed circuit substrate (FPC) or the like which is connected to the external device, to the terminal portion 730T, the external device and the circuit substrate 70 are connected. Each pixel circuit 711 provided on the circuit substrate can be driven by a signal from the external device.

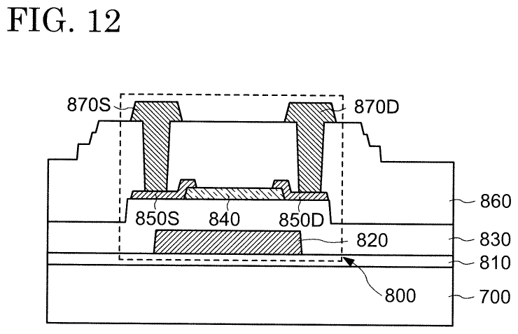

Next, a thin film transistor (TFT) included in the pixel circuit 711, the gate driver circuit 720G, and the source driver circuit 720S are described with reference to FIG. 12.

FIG. 12 is a schematic cross-sectional view of a TFT 800 in the circuit substrate 70 used in the method for transferring the element according to the embodiment of the present invention.

As shown in FIG. 12, the TFT 800 includes a base layer 810, a gate electrode layer 820, a gate insulating layer 830, a semiconductor layer 840, a source electrode layer 850S, a drain electrode layer 850D, a protective layer 860, and a source wiring 870S and a drain wiring layer 870D over the substrate 700.

The gate electrode layer 820, the gate insulating layer 830, and the semiconductor layer 840 are provided in this order over the base layer 810. The source electrode layer 850S is provided at one end of the semiconductor layer 840, and the drain electrode layer 850D is provided at the other end of the semiconductor layer. The source electrode layer 850S and the drain electrode layer 850D are electrically connected to the semiconductor layer 840 on the upper surface and the side surface of the semiconductor layer 840. The protective layer 860, the source wiring layer 870S, and the drain wiring layer 870D are provided over the semiconductor layer 840, the source electrode layer 850S, and the drain electrode layer 850D. The source wiring layer 870S and the drain wiring layer 870D are connected to the source electrode layer 850S and the drain electrode layer 850D, respectively, through openings provided in the protective layer 860. For convenience of explanation, 850S is referred to as a source electrode layer and 850D is referred to as a drain electrode layer, but the functions of the source electrode layer 850S and the drain electrode layer 850D may be interchanged. Similarly, the functions of the source wiring layer 870S and the drain wiring layer 870D may be interchanged.

For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) can be used as the base layer 810, the gate insulating layer 830, and the protective layer 860. Here, SiOₓN_{y} and AlOₓN_{y} are respectively a silicon compound and an aluminum compound containing nitrogen (N) in an amount smaller than that of oxygen (O). Further, SiNₓO_{y} and AlNₓO_{y} are respectively a silicon compound and an aluminum compound which contain a smaller amount of oxygen than nitrogen.

For example, copper (Cu), aluminum (Al), titanium (Ti), chromium (Cr), cobalt (Co), nickel (Ni), molybdenum (Mo), hafnium (Hf), tantalum (Ta), tungsten (W), bismuth (Bi), or alloys or compounds thereof can be used for the gate electrode layer 820, source electrode layer 850S, drain electrode layer 850D, source wiring layer 870S, and drain wiring layer 870D.

For example, a silicon semiconductor such as amorphous silicon or polysilicon, or an oxide semiconductor such as ZnO or IGZO can be used for the semiconductor layer 840.

Further, although not shown, an insulating layer for flattening the unevenness of the TFT 800 described above can be provided over the source wiring layer 870S and the drain wiring layer 870D. For example, an organic insulating material such as an acrylic resin or a polyimide resin can be used for the insulating layer to be flattened. An electrode electrically connected to the element 610 can be provided on the insulating layer to be flattened, and is electrically connected to the source electrode layer 850S or the drain electrode layer 850D.

### [3. Transfer Method]

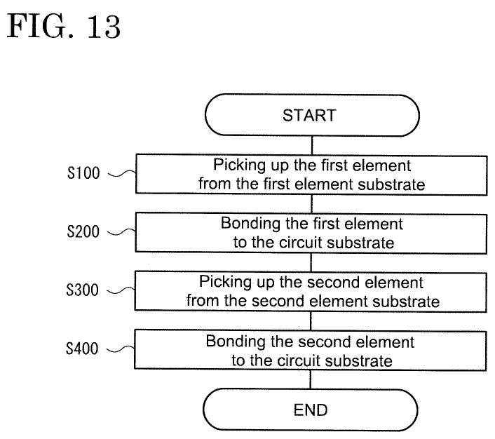

FIG. 13 is a flowchart of the method for transferring the element 610 according to the embodiment of the present invention.

The method for transferring the element according to the present embodiment includes a step of picking up the first element 610R from the first element substrate 60R using the transfer substrate 10 (S100), a step of bonding the picked-up first element 610R to the circuit substrate 70 (S200), a step of picking up the second element 610G from the second element board 60G using the transfer substrate 10 (S300), and a step of bonding the picked-up second element 610G to the circuit substrate 70 (S400).

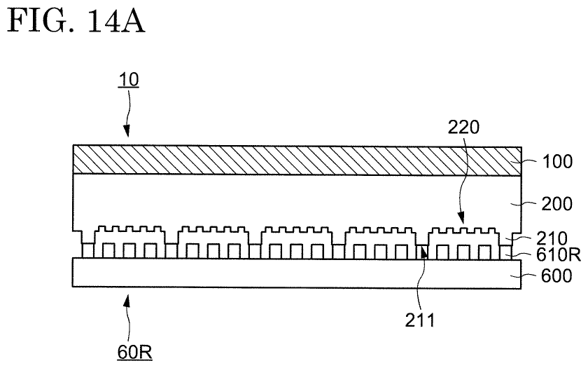

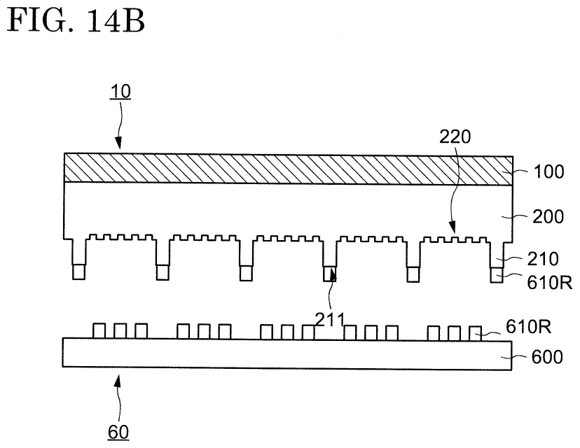

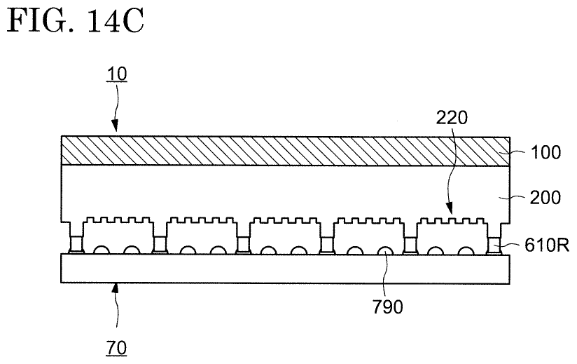

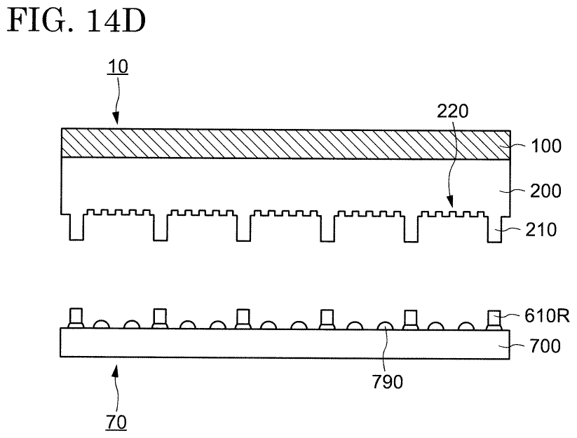

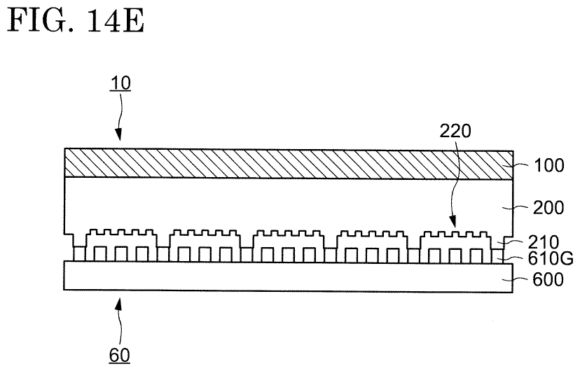

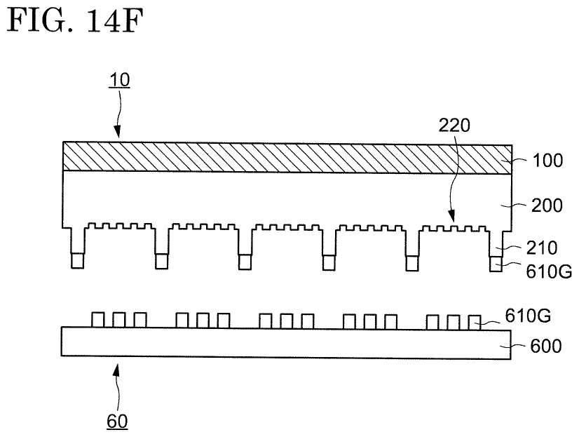

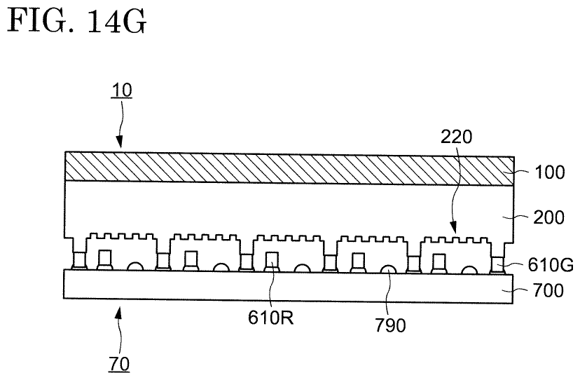

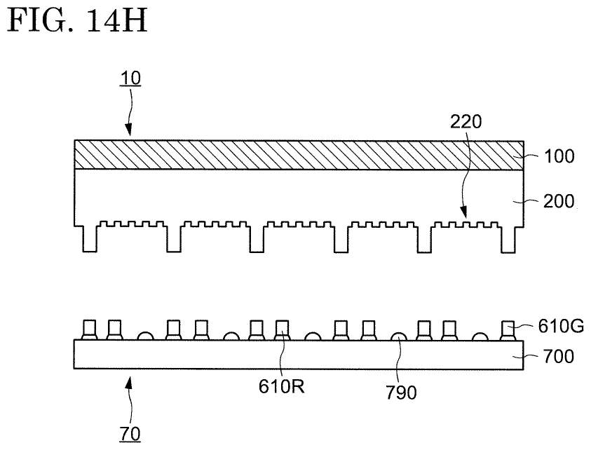

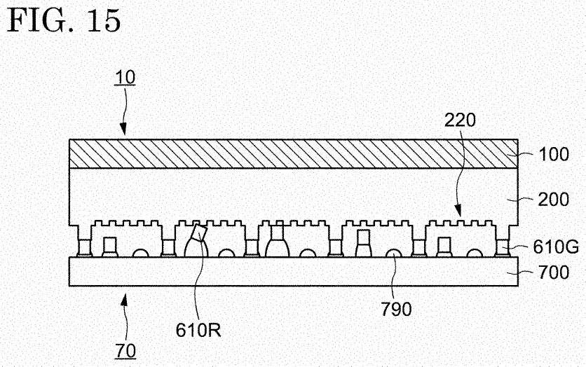

Hereinafter, the method for transferring the element is described in detail with reference to FIGS. 14A to 14H and 15.

FIGS. 14A to 14H are schematic cross-sectional views showing the method for transferring the element according to the embodiment of the present invention.

FIG. 14A shows a state in which the transfer substrate 10 is pressed against the first element substrate 60R in step S100. The head surface 211 of the projection portion 210 of the transfer substrate 10 is in contact with the first element 610R of the first element substrate 60R. Further, the projection portion 210 is compressed by receiving a repulsive force from the first element 610R. Therefore, the length (height) of the projection portion 210 in this state is smaller than the length of the projection portion 210 in a normal state.

FIG. 14B shows a state in which the transfer substrate 10 is separated from the first element substrate 60R in step S100. The adhesive force between the first element 610R and the head surface 211 is larger than the adhesive force between the first element 610R and the support substrate 600. Therefore, the first element 610R, which is in contact with the projection portion 210, is separated from the support substrate 600 and is picked up by the projection portion 210 of the transfer substrate 10. Further, the length of the projection portion 210 returns to the length in the normal state.

FIG. 14C shows a state in which the transfer substrate 10 having picked-up the first element 610R is pressed against the circuit substrate 70 in step S200. The circuit substrate 70 is provided with a conductive adhesive 790. The conductive adhesive 790 is, for example, an adhesive containing a conductive filler. Further, the conductive adhesive 790 may be a thermosetting adhesive or a photocurable adhesive. The conductive adhesive 790 fixes the first element 610R to the circuit substrate 70 and electrically connects the first element 610R and the wiring provided on the circuit substrate 70.

The first element 610R picked-up by the transfer substrate 10 is in contact with the conductive adhesive 790. There are some variations in the size and height of the conductive adhesive 790. Therefore, in order to bond the first element 610R to the circuit substrate 70 in consideration of the variation in the conductive adhesive 790, it is necessary to apply a certain amount of force to press the transfer substrate 10 against the circuit substrate 70. The projection portion 210 is compressed by receiving the repulsive force from the first element 610R. Therefore, the length of the projection portion 210 in this state is smaller than the length of the projection portion 210 in the normal state.

FIG. 14D shows a state in which the transfer substrate 10 is separated from the circuit substrate 70 in step S200. The adhesive force between the first element 610R and the conductive adhesive 790 is larger than the adhesive force between the first element 610R and the head surface 211. Therefore, the first element 610R picked-up by the projection portion 210 is separated from the projection portion 210 and transferred to the circuit substrate 70. Further, the length of the projection portion 210 returns to the length in the normal state.

FIG. 14E shows a state in which the transfer substrate 10 is pressed against the second element substrate 60G in step S300. The head surface 211 of the projection portion 210 of the transfer substrate 10 is in contact with the second element 610G of the second element substrate 60G. Further, the projection portion 210 is compressed by receiving a repulsive force from the second element 610G. Therefore, the length of the projection portion 210 in this state is smaller than the length of the projection portion 210 in the normal state. The transfer substrate 10 used in step S300 does not have to be the same as the transfer substrate 10 that picks up the first element 610R. Another transfer substrate 10 may be used for picking up the second element 610G.

FIG. 14F shows a state in which the transfer substrate 10 is separated from the second element substrate 60G in step S300. The adhesive force between the second element 610G and the head surface 211 is larger than the adhesive force between the second element 610G and the support substrate 600. Therefore, the second element 610G, which is in contact with the projection portion 210, is separated from the support substrate 600 and picked up by the projection portion 210 of the transfer substrate 10. Further, the length of the projection portion 210 returns to the length in the normal state.

FIG. 14G shows a state in which the transfer substrate 10 having picked-up the second element 610G is pressed against the circuit substrate 70 in step S400. The second element 610G is in contact with the conductive adhesive 790 to which the first element 610R is not bonded. Also, the transfer substrate 10 is pressed against the circuit substrate 70 by applying a certain amount of force, so that the projection portion 210 is compressed by receiving the repulsive force from the second element 610G. Therefore, the length of the projection portion 210 in this state is smaller than the length of the projection portion 210 in the normal state.

FIG. 14H shows a state in which the transfer substrate 10 is separated from the circuit substrate 70 in step S400. The adhesive strength between the second element 620G and the conductive adhesive 790 is larger than the adhesion between the second element 620G and the head surface 211. Therefore, the second element 610G picked-up by the projection portion 210 is separated from the projection portion 210 and transferred to the circuit substrate 70. Further, the length of the projection portion 210 returns to the length in the normal state.

The same steps can be repeated to pick up the third element 610B from the third element substrate 60B using the transfer substrate 10, and to bond the picked-up third element 610B to the circuit substrate 70. By using the first element 610R as a red micro LED, the second element 610G as a green micro LED, and the third element 610B as a blue micro LED and bonding the first element 610R, the second element 610G, and the third element in the pixels of the circuit substrate 70, a full-color display device can be obtained.

Further, the first element 610R, the second element 610G, and the third element 610B are used as micro ultraviolet LEDs, and a red phosphor, a green phosphor, and a blue phosphor are provided on the side where light is emitted from the micro ultraviolet LED to convert the emitted ultraviolet light with a phosphor so that a full-color display device can be obtained.

FIG. 15 a schematic cross-sectional view showing the method for transferring the element 610 according to the embodiment of the present invention. Specifically, FIG. 15 shows a state closer to reality than the state shown in FIG. 14G.

As shown in FIG. 15, the first element 610R bonded to the conductive adhesive 790 can take on various states due to variations in the size of the conductive adhesive 790 and the position and orientation of the bonded first element 610R. Therefore, when the transfer substrate 10 picking-up the second element 610G is pressed against the circuit substrate 70, the first surface 201 of the elastic body 200 of the transfer substrate 10 may be in contact with the first element 610R. In this embodiment, since the elastic body 200 of the transfer substrate 10 is provided with the groove portion 220, the adhesiveness of the first surface 201 is weak, and it is possible to prevent the first element 610R from being picked up again.

Each of the embodiments described above as an embodiment of the present invention can be appropriately combined and implemented as long as they do not contradict each other. Additions, deletion, or design changes of constituent elements, or additions, omissions, or changes to conditions of steps as appropriate based on a display device of the respective embodiments are also included within the scope of the present invention as long as the gist of the present invention is provided.

Other effects of the action which differ from those brought about by each of the above described embodiments, but which are apparent from the description herein or which can be readily predicted by those skilled in the art, are naturally understood to be brought about by the present invention.

What is claimed is:

1. A transfer substrate for an element comprising:
a plurality of projection portions projecting from a first surface of an elastic body; and
a first groove portion and a second groove portion, each of the first groove portion and the second groove portion depressed internally from the first surface of the elastic body and extending in a first direction,
wherein a depth of the second groove portion is greater than a depth of the first groove portion.

2. The transfer substrate for an element according to claim 1, wherein at least one of the first groove portion and the second groove portion is provided from one edge surface of the elastic body to another edge surface of the elastic body.

3. The transfer substrate for an element according to claim 1, wherein the first groove portion and the second groove portion are provided between the plurality of projection portions.

4. The transfer substrate for an element according to claim 1, wherein the depth of each of the first groove portion and the second groove portion is smaller than a height of the plurality of projection portions.

5. The transfer substrate for an element according to claim 1, wherein at least one of the first groove portion and the second groove portion has a rectangular cross-sectional shape.

6. The transfer substrate for an element according to claim 1, wherein a side surface of at least one of the first groove portion and the second groove portion comprises a taper.

7. The transfer substrate for an element according to claim 1, wherein at least one of the first groove portion and the second groove portion comprises a curved surface.

8. The transfer substrate for an element according to claim 1, wherein the elastic body is a rubber.

9. The transfer substrate for an element according to claim 1, wherein the elastic body is a silicone rubber.

10. The transfer substrate for an element according to claim 1, wherein a support is provided on a second surface opposite to the first surface of the elastic body.

11. The transfer substrate for an element according to claim 10, wherein the support is a quartz.

12. The transfer substrate for an element according to claim 1, wherein the element is an LED.
